(19) United States
(12) Patent Application Publication
(10) Pub. No.: US 2026/0324488 A1
(43) Pub. Date: Oct. 15, 2026

(54) LOCATION OF COMPONENT USING WIRE BOND STUD BUMP(S) AND COMPONENT CAPTURE FEATURE

(71) Applicant: Qorvo US, Inc., Greensboro, NC (US)

(72) Inventor: David B. Crittenden, Celina, TX (US)

(21) Appl. No.: 19/535,682

(22) Filed: Feb. 10, 2026

Related U.S. Application Data
(60) Provisional application No. 63/789,172, filed on Apr. 15, 2025.

(51) Int. Cl. H10W 72/50; H10W 72/00; H10W 90/00

(52) U.S. Cl. CPC H10W 72/5434; H10W 72/07502; H10W 72/536; H10W 72/537; H10W 90/754

(57) ABSTRACT

Aspects of the disclosure advantageously provide an assembly for microelectronic components and a method for producing the same. The microelectronic assembly includes a carrier configured to receive at least one wire bond stud bump on a surface of the carrier; one or more wire bond stud bumps disposed at one or more locations on the surface of the carrier; and a component fastened to the carrier via one or more wire bond stud bumps. In various embodiments, the component may include at least one capture feature configured to accommodate, and/or for placement of, at least one of the wire bond stud bumps. The capture feature may also include a milled-out area at edge of the component, an edge castellation, a countersink, a blind hole, a through hole, or any other feature that permits a wire bond stud bump to fit partially or fully within the capture feature.

### CROSS-REFERENCE TO RELATED APPLICATION

This application claims priority to U.S. Patent Application No. 63/789,172, filed Apr.15, 2025, all of which is incorporated by reference herein in its entirety.

### TECHNICAL FIELD

The present disclosure relates generally to wire bonding, and in particular, relates to wire bond placement and location registration using wire bond stud bumps that can be used for component capture in production of microelectronic assemblies.

### BACKGROUND

Microelectronic assemblies, including, e.g., carrier plate, lead frame, laminate, etc., strive to fit the most material in the least area and/or volume. As a result, various designs and methodologies are developed so as to utilize, for example, wire bond stud bumps to locate a particular component within the assembly, e.g., stud bumps at corners of die being attached via gold-tin (AuSn) solder. Consequently, these locating features can limit the minimum spacing between components, which in turn limits the shortest interconnect between components. Thus, there is a need for an improved approach that can be implemented in microelectronic productions.

### SUMMARY

Embodiments of the present disclosure include a method for preparing a microelectronic assembly using a combination of component capture features and stud bumps to improve component placement accuracy, interconnect options, component placement density, and minimum component interconnect length. Aspects of the disclosure advantageously provide one or more methods for improving microelectronic production via strategic improvements in component placement accuracy, interconnect options, component placement density, and minimum component interconnect length using wire bond stud bumps.

In an exemplary aspect, an assembly for microelectronic components is provided. The assembly includes a carrier configured to receive at least one wire bond stud bump on a surface of the carrier; one or more wire bond stud bumps disposed at one or more locations on the surface of the carrier; and a component located on the carrier via the one or more wire bond stud bumps, the component comprising at least one capture feature configured to accommodate, and/or for placement of, at least one of the one or more wire bond stud bumps.

In one or more embodiments, the carrier may include a metal or a metal-clad material. In one or more embodiments, the one or more wire bond stud bumps each include a wire bond attached to the carrier at a first end of the wire bond and unconnected at a second end of the wire bond. In one or more embodiments, the one or more wire bond stud bumps may include at least two wire bond stud bumps having two different diameters. In one or more embodiments, the component may include a non-metallic body having at least one metallized surface.

In one or more embodiments, the at least one capture feature may include one of a milled-out area at edge of the component, an edge castellation, a countersink, a blind hole, a through hole, or any other feature that permits a wire bond stud bump to fit partially or fully within the capture feature. In one or more embodiments, the at least one capture feature may include a multiple-capture feature configured to be used for registration and fastening of the component to the carrier with at least one degree of freedom of movement suitable for forming an interconnect. In one or more embodiments, the at least one capture feature may include a through hole with tapered walls having a first opening and a second opening that has a larger diameter than that of the first opening.

In an exemplary aspect, a method is provided. The method includes identifying one or more locations on a surface of a carrier for placement of one or more wire bond stud bumps; placing at least one of the one or more wire bond stud bumps at one of the one or more locations, the one or more locations defining orientation and placement of a component; and fastening the component to the carrier via the one or more wire bond stud bumps, the component comprising at least one capture feature configured to accommodate, and/or for placement of, at least one of the one or more wire bond stud bumps.

In one or more embodiments of the method, the at least one capture feature may include one of a milled-out area at edge of the component, an edge castellation, a countersink, a blind hole, a through hole, or any other feature that permits a wire bond stud bump to fit partially or fully within the capture feature. In one or more embodiments, the at least one capture feature may include a through hole with tapered walls having a first opening and a second opening that has a larger diameter than that of the first opening.

In one or more embodiments of the method, fastening the component to the carrier may further include placing at least two wire bond stud bumps having two different diameters, wherein a first of the at least two wire bond stud bumps has a diameter smaller than both first and second openings, and a second of the at least two wire bond stud bumps has a diameter larger than that of the first and smaller than that of the second opening.

In one or more embodiments of the method, the carrier may include a metal or a metal-clad material and/or wherein the component comprises a non-metallic body having at least one metallized surface. In one or more embodiments, the one or more wire bond stud bumps each include a wire bond attached to the carrier at a first end of the wire bond and unconnected at a second end of the wire bond. In one or more embodiments, a microelectronic assembly is produced in accordance with the method described above.

In an exemplary aspect, a semiconductor package is provided. In one or more embodiments, the semiconductor package includes a microelectronic assembly comprising one or more wire bond stud bumps disposed at one or more locations on a surface of a carrier, and a component fastened to the carrier via the one or more wire bond stud bumps, wherein the component comprises at least one capture feature configured to accommodate, and/or for placement of, at least one of the one or more wire bond stud bumps.

In one or more embodiments of the semiconductor package, the at least one capture feature may include one of a milled-out area at edge of the component, an edge castellation, a countersink, a blind hole, a through hole, or any other feature that permits a wire bond stud bump to fit partially or fully within the capture feature. In one or more embodiments, the at least one capture feature may include a through hole with tapered walls having a first opening and a second opening that has a larger diameter than that of the first opening.

In one or more embodiments of the semiconductor package, the component is fastened to the carrier further via at least two wire bond stud bumps having two different diameters, wherein a first of the at least two wire bond stud bumps has a diameter smaller than both first and second openings, and a second of the at least two wire bond stud bumps has a diameter larger than that of the first and smaller than that of the second opening. In one or more embodiments, the carrier may include a metal or a metal-clad material and/or wherein the component comprises a non-metallic body having at least one metallized surface.

Additional aspects, embodiments, implementations, features, and advantages of the present disclosure will become apparent from the following detailed description.

### BRIEF DESCRIPTION OF THE DRAWINGS

Illustrative embodiments of the present disclosure will be described with reference to the accompanying drawings, of which:

FIG. 1 illustrates an example assembly for microelectronics components, according to aspects of the present disclosure.

FIGS. 2A, 2B, 2C, 2D, and 2E illustrate various embodiments of an example assembly for microelectronics components, according to aspects of the present disclosure.

FIG. 3 illustrates a flowchart for a method for forming an assembly, according to aspects of the present disclosure.

FIG. 4 illustrates a semiconductor package comprising a microelectronic assembly, according to aspects of the present disclosure.

### DETAILED DESCRIPTION

For the purposes of promoting an understanding of the principles of the present disclosure, reference will now be made to the embodiments illustrated in the drawings, and specific language will be used to describe the same. It is nevertheless understood that no limitation to the scope of the disclosure is intended. Any alterations and further modifications to the described devices, systems, and methods, and any further application of the principles of the present disclosure are fully contemplated and included within the present disclosure as would normally occur to one skilled in the art to which the disclosure relates. In particular, it is fully contemplated that the features, components, and/or steps described with respect to one embodiment may be combined with the features, components, and/or steps described with respect to other embodiments of the present disclosure. For the sake of brevity, however, the numerous iterations of these combinations will not be described separately.

In accordance with one or more embodiments, an assembly for microelectronic components and one or more methods of forming such assemblies are provided. Benefits provided by the disclosed assemblies and methodologies may include, but not limited to, providing assemblies where various components may be placed closer together, with possible improvement in registration of component(s), and in some implementations, allows for access to interconnect pads beneath the topmost surfaces or components if multiple components are stacked. In some respects, permanent attachments or fastening of components, either via stacked arrangement or adjacent or proximity arrangements may be suitable. In some implementations, the disclosed technologies may enable improvement of component placement accuracy, make available various interconnect options, increase component placement density, and with minimum component interconnect length, if a combination of the one or more component capture features and wire bond stud bumps are used. In one or more embodiments, the disclosed component capture features can take the form of one or more milled-out areas at the edges of the component, an edge castellation, a countersink, a blind hole, a through hole, or any other feature that permit one or more wire bond stud bumps to fit partially or fully within the capture features.

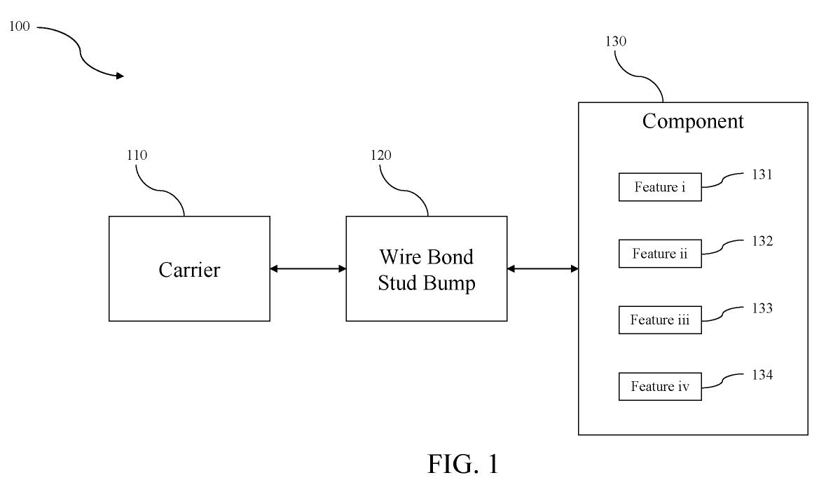

Various embodiments disclosed herein provide an assembly for microelectronic components and one or more methods of forming such assembly, the disclosures of which are described in further detail with respect to the FIGS. 1, 2A, 2B, 2C, 2D, 2E, 3, and 4.

FIG. 1 illustrates an example assembly 100 for microelectronics components, according to aspects of the present disclosure. As described herein, the assembly 100 may be configured for use with assembling microelectronic components, where various components may be placed closer together, with each component registered and located on the substrate/carrier, and in some implementations, allows for access to interconnect pads beneath the topmost surfaces or components if multiple components are stacked. In one or more embodiments, the assembly 100 may be configured for permanent attachment or fastening of components, either via stacked arrangement or adjacent arrangements. In one or more embodiments, the assembly 100 may be produced or manufactured using advanced semiconductor packaging techniques as disclosed herein. In one or more embodiments, a semiconductor package may include assembly 100, as disclosed herein. In one or more embodiments, a wireless device may include the semiconductor package that includes assembly 100, as disclosed herein.

As illustrated in FIG. 1, the assembly 100 includes a carrier 110 (can also be referred to herein as a “substrate 110”) that is configured to receive at least one wire bond stud bump 120 on a surface of the carrier 110. In one or more embodiments, the carrier 110 may include a metal or a metal-clad material, or any suitable material that can be used as a carrier or a substrate in a microelectronic assembly.

As further illustrated in FIG. 1, the assembly 100 includes one or more wire bond stud bumps 120 that are disposed at one or more locations on the surface of the carrier 110. In one or more embodiments, one or more wire bond stud bumps 120 may include a wire bond attached to the carrier 110 at one end (e.g., a first end) of the wire bond and the other end (e.g., a second end) of the wire bond being unconnected. In one or more embodiments, one or more wire bond stud bumps 120 may include at least two wire bond stud bumps that have two different diameters. In various embodiments, wire bond stud bumps 120 with two different diameters may allow forming of stacked wire bond stud bumps that can help fastening or attaching of various components to the carrier 110.

As further illustrated in FIG. 1, the assembly 100 includes a component 130 that is fastened to the carrier 110 via one or more wire bond stud bumps 120. Using one or more properly placed wire bond stud bumps 120, the component 130 can be attached to the carrier 110, reversibly, removably, or permanently, in accordance with one or more embodiments. In one or more embodiments, the component 130 may include a non-metallic body having at least one metallized surface.

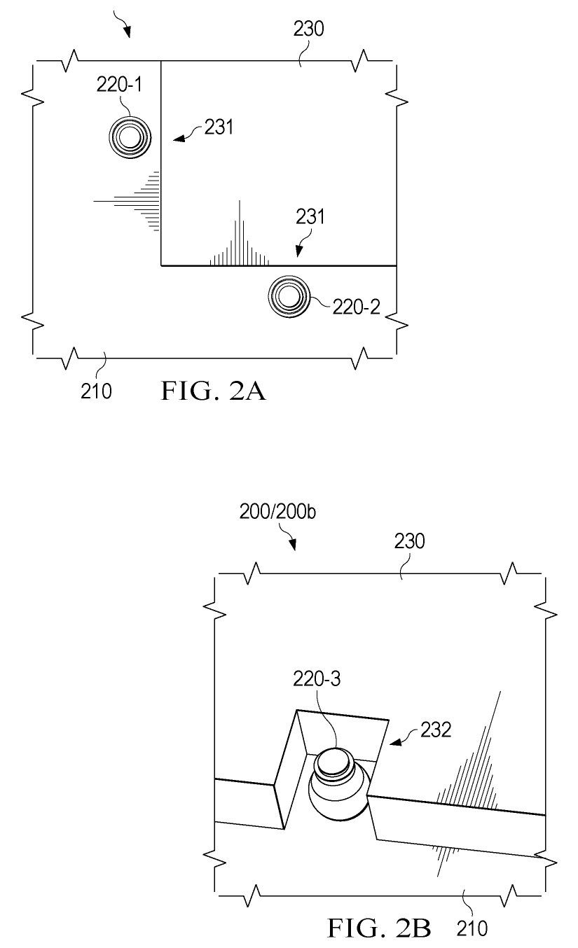

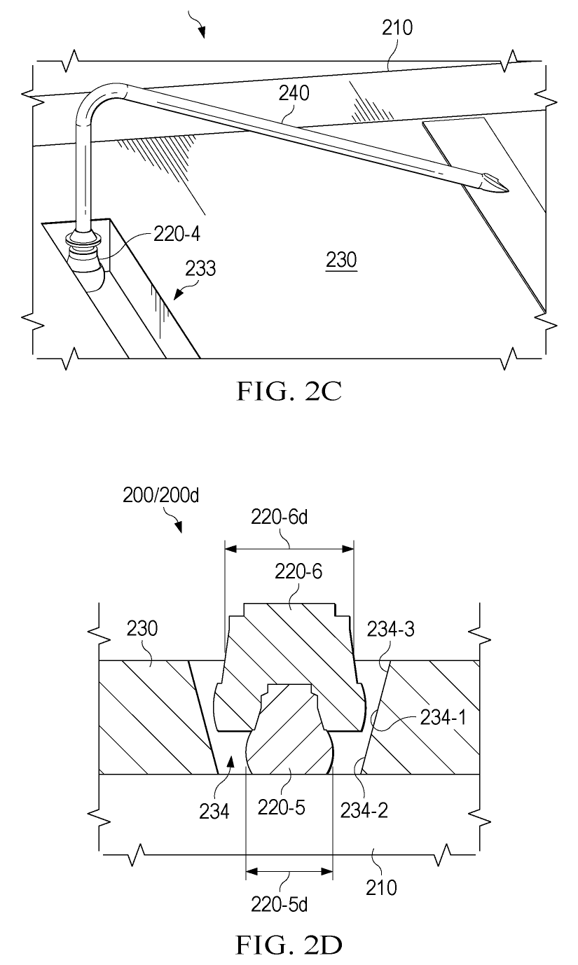

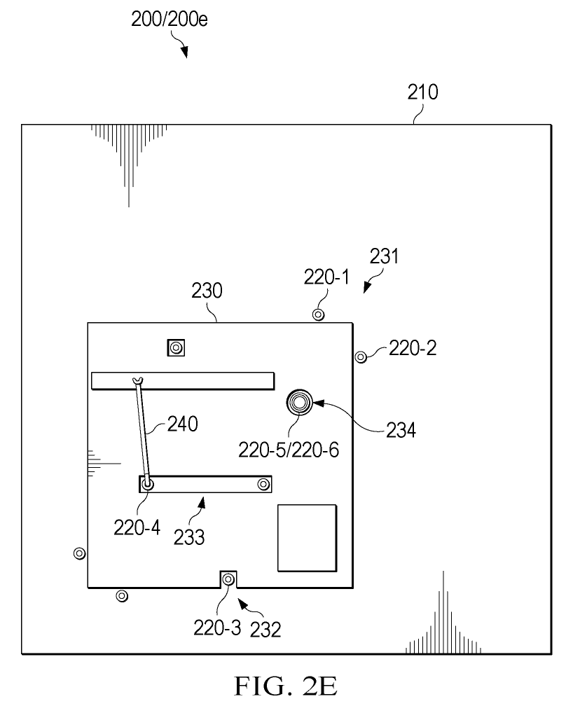

As further illustrated, the component 130 may include one or more capture features (also referred to herein simply as “features”), such as, feature i 131, feature ii 132, feature iii 133, and feature iv 134, or any additional suitable features. In one or more embodiments, at least one of the capture features, namely, features 131, 132, 133, and/or 134, may be configured to accommodate, and/or for placement of, at least one of the one or more wire bond stud bumps 120. In one or more embodiments, the at least one capture feature, namely, any one of features 131, 132, 133, and/or 134, may include one of a milled-out area at edge of the component, an edge castellation, a countersink, a blind hole, a through hole, or any other feature that permits a wire bond stud bump 120 to fit partially or fully within the capture feature (e.g., one of features 131, 132, 133, and/or 134). In one or more embodiments, the at least one capture feature may include a multiple-capture feature (e.g., any combination of one or more features 131, 132, 133, and/or 134) configured to be used for registration and fastening of the component 130 to the carrier 110 with at least one degree of freedom of movement suitable for forming an interconnect (not shown in FIG. 1). In one or more embodiments, the at least one capture feature (e.g., one of features 131, 132, 133, and/or 134) may include a through hole with tapered walls having a first opening and a second opening that has a larger diameter than that of the first opening, the embodiments of which are described below in further detail with respect to FIGS. 2A, 2B, 2C, 2D, and 2E.

FIGS. 2A, 2B, 2C, 2D, and 2E illustrate various embodiments of an example assembly 200 for microelectronics components, according to aspects of the present disclosure. As described herein, the assembly 200, via embodiments 200a, 200b, 200c, 200d, and 200e, may be configured for use with assembling microelectronic components, where various components may be placed closer together, with each component registered and located on the substrate/carrier, and in some implementations, allows for access to interconnect pads beneath the topmost surfaces or components if multiple components are stacked. In one or more embodiments, the assembly 200, via embodiments 200a, 200b, 200c, 200d, and 200e, may be configured for permanent attachment or fastening of components, either via stacked arrangement or adjacent arrangements. In one or more embodiments, the assembly 200, including embodiments 200a, 200b, 200c, 200d, and 200e, may be produced or manufactured using advanced semiconductor packaging techniques as disclosed herein. In one or more embodiments, a semiconductor package may include assembly 200, including embodiments 200a, 200b, 200c, 200d, and 200e, as disclosed herein. In one or more embodiments, a wireless device may include the semiconductor package that includes assembly 200, including embodiments 200a, 200b, 200c, 200d, and 200e, as disclosed herein.

As illustrated in FIGS. 2A, 2B, 2C, 2D, and 2E, the assembly 200 includes a carrier 210 (also referred to herein as a “substrate 210”) that is configured to receive at least one wire bond stud bump 220 on a surface of the carrier 210. In one or more embodiments, the carrier 210 may include a metal or a metal-clad material, or any suitable material that can be used as a carrier or a substrate in a microelectronic assembly.

As further illustrated in FIGS. 2A, 2B, 2C, 2D, and 2E, the assembly 200 includes one or more wire bond stud bumps 220, namely, wire bond stud bumps 220-1, 220-2, 220-3, 220-4, 220-5, and/or 220-6, that are disposed at one or more locations on the surface of the carrier 210. In one or more embodiments, one or more wire bond stud bumps 220-1, 220-2, 220-3, 220-4, 220-5, and/or 220-6 may include a wire bond attached to the carrier 210 at one end (e.g., a first end) of the wire bond and the other end (e.g., a second end) of the wire bond being unconnected, as illustrated in FIGS. 2A, 2B, 2C, 2D, and 2E. In one or more embodiments, one or more wire bond stud bumps 220 include at least two wire bond stud bumps, namely wire bond stud bumps 220-5, and 220-6, that have two different diameters 220-5dand 220-6d, respectively, as illustrated in FIG. 2D. Accordingly, wire bond stud bumps 220-6 with its diameter 220-6d has a larger diameter than the diameter 220-5d of wire bond stud bumps 220-5. In such embodiments, wire bond stud bumps 220 with two different diameters allow for forming of stacked wire bond stud bumps as shown in FIG. 2D, that can help with fastening or attaching of various components to the carrier 210, in accordance with one or more embodiments.

As further illustrated in FIGS. 2A, 2B, 2C, 2D, and 2E, the assembly 200 includes a component 230 that is fastened to the carrier 210 via one or more wire bond stud bumps 220, namely, wire bond stud bumps 220-1, 220-2, 220-3, 220-4, 220-5, and/or 220-6, that are disposed at various locations of the carrier 210. Using one or more properly placed wire bond stud bumps 220-1, 220-2, 220-3, 220-4, 220-5, and/or 220-6, the component 230 may be attached to the carrier 210 in any configuration, form, or arrangement, reversibly, removably, or permanently, in accordance with one or more embodiments. In one or more embodiments, the component 230 may include a non-metallic body having at least one metallized surface.

As shown in FIGS. 2A, 2B, 2C, 2D, and 2E, the component 230 may include one or more capture features (also referred to herein simply as “features”), such as but not limited to, feature 231, feature 323, feature 233, and feature 234, or any additional suitable features (not shown). In accordance with one or more embodiments, at least one of the capture features, namely, features 231, 232, 233, and/or 234, may be configured to accommodate, and/or for placement of, at least one of the one or more wire bond stud bumps 220, namely, wire bond stud bumps 220-1, 220-2, 220-3, 220-4, 220-5, and/or 220-6. In one or more embodiments, the at least one capture feature, namely, any one of features 231, 232, 233, and/or 234, may include one of a milled-out area at edge of the component, an edge castellation, a countersink, a blind hole, a through hole, or any other feature that permits a wire bond stud bump 220, namely, any of wire bond stud bumps 220-1, 220-2, 220-3, 220-4, 220-5, and/or 220-6, to fit partially or fully within the capture feature.

FIG. 2A depicts a perspective view of the assembly 200 for microelectronics components, according to aspects of the present disclosure. Embodiment 200a of the assembly 200 shown in FIG. 2A includes the carrier 210 with wire bond stud bumps 220-1 and 220-2 placed in a configuration on a surface of the carrier 210 such that it can receive the component 230 at the component’s edge or corner. This feature is designated as component capture feature 231, as depicted in FIG. 2A. In other words, by placing two wire bond stud bumps 220-1 and 220-2 in a configuration as shown in FIG. 2A, the component 230 can be placed with its edge or corner against the two wire bond stud bumps 220-1 and 220-2, allowing the component 230 to be attached or fastened reversibly, removably, or permanently to the carrier 210.

FIG. 2B depicts another perspective view of the assembly 200 for microelectronics components, according to aspects of the present disclosure. Embodiment 200b of the assembly 200 shown in FIG. 2B includes the carrier 210 with the wire bond stud bump 220-3 placed in a configuration to accommodate one or more milled-out areas at the edges of the component 230 or an edge castellation of the component 230 to form the capture feature 232, in one or more embodiments. In other words, by placing the wire bond stud bump 220-3 in a configuration as shown in FIG. 2B, the wire bond stud bump 220-3 disposed on the surface of the carrier 210 can be used as a placement guide to register or orientate the component 230 by placing its capture feature 232, namely, its milled-out area or edge castellation, against the wire bond stud bump 220-3. This registration or placement setup may allow the component 230 to be attached or fastened reversibly, removably, or permanently to the carrier 210, in accordance with one or more embodiments disclosed herein.

FIG. 2C depicts a perspective view of the assembly 200 for microelectronics components, according to aspects of the present disclosure. Embodiment 200c of the assembly 200 shown in FIG. 2C includes the carrier 210 with wire bond stud bump 220-4 placed in a configuration on a surface of the carrier 210 such that it can receive the component 230 at the component’s capture feature 233. As shown in FIG. 2C, the capture feature 233 is a trench within the component 230, which can be placed on the carrier 210 after the wire bond stud bump 220-4 is disposed on the surface of the carrier 210. Once the capture feature 233 of the component 230 is placed and oriented in a desired configuration, additional components, such as but not limited to, an interconnect 240 can be placed or disposed atop the wire bond stud bump 220-4, as shown in FIG. 2C, where one end of the interconnect 240 is attached to the wire bond stud bump 220-4 and another end of the interconnect 240 is attached to another portion or component (not specified).

In one or more embodiments, the capture feature 233 of the component 230 may include a multiple-capture feature, e.g., similar to capture feature 232 plus slidable or movable along the trench, indicating at least one degree of freedom of movement for the component 230 with respect to the carrier 210. This arrangement can be used for registration and fastening of the component 230 to the carrier 210 with at least one degree of freedom of movement suitable for forming an interconnect, such as interconnect 240, as shown in FIG. 2C. Since the capture feature 233 is shown as a trench, it can be understood that the component 230 can be movable along the long direction of the capture feature 233. In other words, by placing the wire bond stud bump 220-4 on the carrier 210 and placing the component 230 with its capture feature 233 in a configuration as shown in FIG. 2C, the component 230 can be considered movable (or “slidable”) against the wire bond stud bumps 220-4, thereby allowing the component 230 to be movably attached or fastened to the carrier 210 in a direction along the long direction of the capture feature 233 (i.e., trench).

FIG. 2D depicts a perspective view of the assembly 200 for microelectronics components, according to aspects of the present disclosure. Embodiment 200d of the assembly 200 shown in FIG. 2D includes the carrier 210 with stacked wire bond stud bumps 220-5 and 220-6 placed in a configuration on a surface of the carrier 210 such that it can fasten the component 230 at the component’s capture feature 234.

In one or more embodiments, the capture feature 234 of the component 230 may include a through hole with one or more tapered walls having a first opening and a second opening that has a larger diameter than that of the first opening. For example, as shown in FIG. 2D, the wire bond stud bump 220-5 has a small diameter 220-5d and the wire bond stud bump 220-6 has a large diameter 220-6d. Similarly, the capture feature 234 is a through hole having a tapered wall 234-1 with its small opening 234-2 and its large opening 234-3, as shown in FIG. 2D. After placing the small diameter 220-5d wire bond stud bump 220-5 atop the surface of the carrier 210, the component 230 can be placed on the carrier 210 aligning the through hole capture feature 234 against the wire bond stud bump 220-5. After placing the component 230 against the carrier 210, the large diameter 220-6d wire bond stud bump 220-6 can be placed atop the wire bond stud bump 220-5, thereby securing the component 230 against the carrier 210 such that the component 230 may not be removed as wire bond stud bump 220-6’s large diameter 220-6d is larger than the small opening 234-2 of the through hole capture feature 234, in accordance with one or more embodiments. In other words, the large opening 234-3 of the through hole capture feature 234 is larger than the wire bond stud bump 220-6’s large diameter 220-6d, which is larger than the small opening 234-2 of the through hole capture feature 234, which is larger than the wire bond stud bump 220-5’s small diameter 220-5d, in accordance with one or more embodiments. Said another way, the wire bond stud bump 220-5’s small diameter 220-5d is smaller than the small opening 234-2 of the through hole capture feature 234, which is smaller than the wire bond stud bump 220-6’s large diameter 220-6d, which is smaller than the large opening 234-3 of the through hole capture feature 234.

In one or more embodiments, the differences between any two of small diameter 220-5d, large diameter 220-6d, small opening 234-2, and large opening 234-3 may range between about 5% and about 95%, between about 10% and about 90%, between about 15% and about 85%, between about 20% and about 80%, between about 25% and about 75%, between about 30% and about 65%, between about 40% and about 60%, between about 45% and about 55%, between about 5% and about 50%, between about 10% and about 50%, between about 15% and about 50%, between about 20% and about 50%, between about 25% and about 50%, between about 30% and about 50%, between about 40% and about 50%, between about 45% and about 50%, between about 5% and about 40%, between about 10% and about 40%, between about 15% and about 40%, between about 20% and about 40%, between about 25% and about 40%, between about 30% and about 40%, between about 5% and about 30%, between about 10% and about 30%, between about 15% and about 30%, between about 20% and about 30%, between about 25% and about 30%, inclusive of any ranges therebetween.

FIG. 2E depicts another perspective view of the assembly 200 for microelectronics components, according to aspects of the present disclosure. Embodiment 200e of the assembly 200 shown in FIG. 2E is a combination of embodiments 200a, 200b, 200c, and 200d, wherein each of the capture features 231, 232, 233, and/or 234 are illustrated with corresponding wire bond stud bumps 220-1, 220-2, 220-3, 220-4, 220-5, and/or 220-6. It is to be understood that that any combination of the capture features 231, 232, 233, and/or 234 and wire bond stud bumps 220-1, 220-2, 220-3, 220-4, 220-5, and/or 220-6 may be implemented in a given assembly. As illustrated in FIG. 2E, any combination of the capture features 231, 232, 233, and/or 234 may be configured to accommodate, and/or for placement of, any combination of wire bond stud bumps 220-1, 220-2, 220-3, 220-4, 220-5, and/or 220-6. In one or more embodiments, the capture features 231, 232, 233, and/or 234, may include any combination of a milled-out area, an edge castellation, a countersink, a blind hole, a through hole, or any other feature that permits any of the wire bond stud bumps 220-1, 220-2, 220-3, 220-4, 220-5, and/or 220-6, to fit partially or fully within the capture feature.

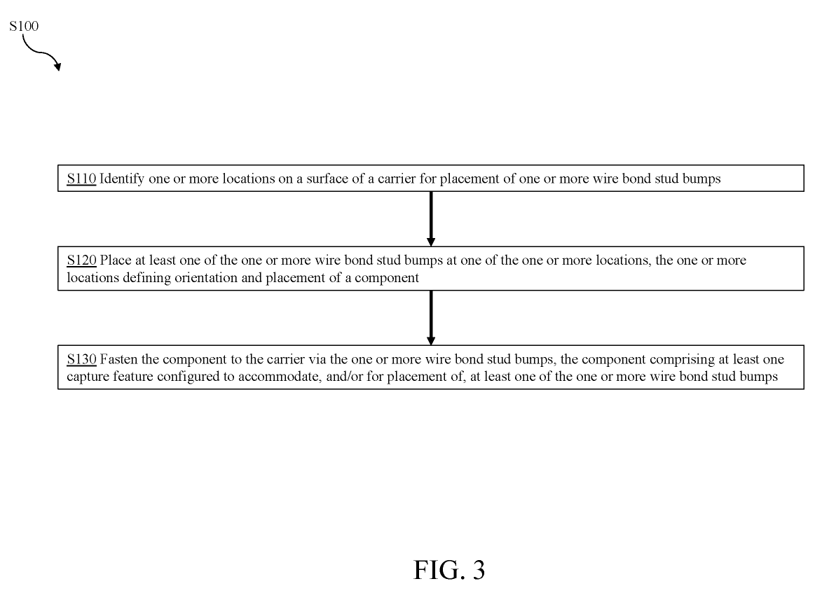

FIG. 3 illustrates a flowchart for a method S100 for forming an assembly for microelectronic components (or simple a microelectronic assembly), according to aspects of the present disclosure. In one or more embodiments, the assembly formed via the method S100 may include an assembly, such as the assembly 100 or assembly 200, as described with respect to FIGS. 1, 2A, 2B, 2C, 2D, and 2E.

As shown in FIG. 2, the method S100 includes, at step S110, identifying one or more locations on a surface of a carrier for placement of one or more wire bond stud bumps. In one or more embodiments, the carrier includes a carrier, such as the carrier 110 or 210, the one or more wire bond stud bumps includes one or more wire bond stud bumps, such as the one or more wire bond stud bumps 120 or 220, namely, 220-1, 220-2, 220-3, 220-4, 220-5, and/or 220-6, as described with respect to FIGS. 1, 2A, 2B, 2C, 2D, and 2E.

The method S100 further includes, at step S120, placing at least one of the one or more wire bond stud bumps at one of the one or more locations, the one or more locations defining orientation and placement of a component. In one or more embodiments, the component includes a component, such as the component 130 or 230, as described with respect to FIGS. 1, 2A, 2B, 2C, 2D, and 2E.

The method S100 further includes, at step S130, fastening the component to the carrier via the one or more wire bond stud bumps, the component comprising at least one capture feature configured to accommodate, and/or for placement of, at least one of the one or more wire bond stud bumps. In one or more embodiments, the capture feature includes a capture feature, such as the capture features 131, 132, 133, 134, 231, 232, 233, and/or 234, as described with respect to FIGS. 1, 2A, 2B, 2C, 2D, and 2E.

In one or more embodiments of the method S100, the at least one capture feature may include one of a milled-out area at edge of the component, an edge castellation, a countersink, a blind hole, a through hole, or any other feature that permits a wire bond stud bump to fit partially or fully within the capture feature. In one or more embodiments, the at least one capture feature may include a through hole with tapered walls having a first opening, such as small opening 234-2 of the through hole capture feature 234, and a second opening, such as large opening 234-3 of the through hole capture feature 234, that has a larger diameter than that of the first opening.

In one or more embodiments of the method S100, fastening the component to the carrier may further include placing at least two wire bond stud bumps having two different diameters, such as small diameter 220-5d of the wire bond stud bump 220-5 and large diameter 220-6d of the wire bond stud bump 220-6, wherein a first of the at least two wire bond stud bumps has a diameter smaller than both first and second openings, and a second of the at least two wire bond stud bumps has a diameter larger than that of the first and smaller than that of the second opening.

In one or more embodiments of the method S100, the carrier may include a metal or a metal-clad material and/or wherein the component comprises a non-metallic body having at least one metallized surface. In one or more embodiments, the one or more wire bond stud bumps each include a wire bond attached to the carrier at a first end of the wire bond and unconnected at a second end of the wire bond. In one or more embodiments, a microelectronic assembly is produced in accordance with the method S100 described above.

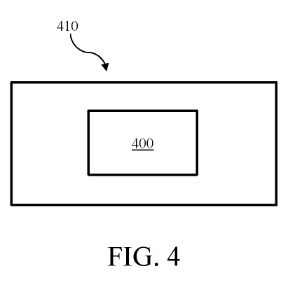

FIG. 4 illustrates a semiconductor package 410 comprising a microelectronic assembly 400, according to aspects of the present disclosure. In some implementations, the semiconductor package 410 may be used in, for example, but not limited to, a computer, a cellular device, a satellite communication device, a wi-fi device, a radar, a global position system device, or any electronic device. In one or more embodiments, the assembly 400 may be produced in accordance with the method S100 described with respect to FIG. 3, and/or may include an assembly, such as the assembly 100 or assembly 200, as described with respect to FIGS. 1, 2A, 2B, 2C, 2D, and 2E. The semiconductor package 410 that includes assembly 400 may implement any RF circuitry used in wireless applications, as an example, such as one or more RF power amplifiers; and the semiconductor package may be coupled to other circuitry for implementing a wireless application, such as a baseband processor or other types of processors.

In one or more embodiments of the semiconductor package 410, the microelectronic assembly 400 includes one or more wire bond stud bumps disposed at one or more locations on a surface of a carrier, and a component fastened to the carrier via the one or more wire bond stud bumps, wherein the component comprises at least one capture feature configured to accommodate, and/or for placement of, at least one of the one or more wire bond stud bumps. In one or more embodiments, the carrier includes a carrier, such as the carrier 110 or 210, the one or more wire bond stud bumps includes one or more wire bond stud bumps, such as the one or more wire bond stud bumps 120 or 220, namely, 220-1, 220-2, 220-3, 220-4, 220-5, and/or 220-6, the component includes a component, such as the component 130 or 230, and the at least one capture feature includes a capture feature, such as the capture features 131, 132, 133, 134, 231, 232, 233, and/or 234, as described with respect to FIGS. 1, 2A, 2B, 2C, 2D, and 2E.

In one or more embodiments of the semiconductor package 410, the at least one capture feature may include one of a milled-out area at edge of the component, an edge castellation, a countersink, a blind hole, a through hole, or any other feature that permits a wire bond stud bump to fit partially or fully within the capture feature. In one or more embodiments, the at least one capture feature may include a through hole with tapered walls having a first opening and a second opening that has a larger diameter than that of the first opening.

In one or more embodiments of the semiconductor package 410, the component is fastened to the carrier further via at least two wire bond stud bumps having two different diameters, wherein a first of the at least two wire bond stud bumps has a diameter smaller than both first and second openings, and a second of the at least two wire bond stud bumps has a diameter larger than that of the first and smaller than that of the second opening. In one or more embodiments, the carrier may include a metal or a metal-clad material and/or wherein the component comprises a non-metallic body having at least one metallized surface. In one or more embodiments, the semiconductor package 410 that includes assembly 400 may be produced via the method S100, as described with respect to FIG. 3.

Persons skilled in the art will recognize that the apparatus, systems, and methods described above can be modified in various ways. Accordingly, persons of ordinary skill in the art will appreciate that the embodiments encompassed by the present disclosure are not limited to the particular exemplary embodiments described above. In that regard, although illustrative embodiments have been shown and described, a wide range of modification, change, and substitution is contemplated in the foregoing disclosure. It is understood that such variations may be made to the foregoing without departing from the scope of the present disclosure. Accordingly, it is appropriate that the appended claims be construed broadly and in a manner consistent with the present disclosure.

1. An assembly for microelectronic components, comprising:
a carrier configured to receive at least one wire bond stud bump on a surface of the carrier;
one or more wire bond stud bumps disposed at one or more locations on the surface of the carrier; and
a component fastened to the carrier via the one or more wire bond stud bumps, the component comprising at least one capture feature configured to accommodate at least one of the one or more wire bond stud bumps.

2. The assembly of claim 1, wherein the carrier comprises a metal or a metal-clad material.

3. The assembly of claim 1, wherein the one or more wire bond stud bumps each comprise a wire bond attached to the carrier at a first end of the wire bond and unconnected at a second end of the wire bond.

4. The assembly of claim 1, wherein the one or more wire bond stud bumps comprise at least two wire bond stud bumps having two different diameters.

5. The assembly of claim 1, wherein the component comprises a non-metallic body having at least one metallized surface.

6. The assembly of claim 1, wherein the at least one capture feature comprises one of a milled-out area at edge of the component, an edge castellation, a countersink, a blind hole, a through hole, or any other feature that permits a wire bond stud bump to fit partially or fully within the capture feature.

7. The assembly of claim 1, wherein the at least one capture feature comprises a multiple-capture feature configured to be used for registration and fastening of the component to the carrier with at least one degree of freedom of movement suitable for forming an interconnect.

8. The assembly of claim 1, wherein the at least one capture feature comprises a through hole with tapered walls having a first opening and a second opening that has a larger diameter than that of the first opening.

9. A method, comprising:
identifying one or more locations on a surface of a carrier for placement of one or more wire bond stud bumps;
placing at least one of the one or more wire bond stud bumps at one of the one or more locations, the one or more locations defining orientation and placement of a component; and
fastening the component to the carrier via the one or more wire bond stud bumps, the component comprising at least one capture feature configured to accommodate at least one of the one or more wire bond stud bumps.

10. The method of claim 1, wherein the at least one capture feature comprises one of a milled-out area at edge of the component, an edge castellation, a countersink, a blind hole, a through hole, or any other feature that permits a wire bond stud bump to fit partially or fully within the capture feature.

11. The method of claim 1, wherein the at least one capture feature comprises a through hole with tapered walls having a first opening and a second opening that has a larger diameter than that of the first opening.

12. The method of claim 11, wherein fastening the component to the carrier further comprises:
placing at least two wire bond stud bumps having two different diameters,
wherein a first of the at least two wire bond stud bumps has a diameter smaller than both first and second openings, and a second of the at least two wire bond stud bumps has a diameter larger than that of the first and smaller than that of the second opening.

13. The method of claim 9, wherein the carrier comprises a metal or a metal-clad material and/or wherein the component comprises a non-metallic body having at least one metallized surface.

14. The method of claim 9, wherein the one or more wire bond stud bumps each comprise a wire bond attached to the carrier at a first end of the wire bond and unconnected at a second end of the wire bond.

15. A microelectronic assembly produced in accordance with the method of claim 9.

16. A semiconductor package, comprising:
a microelectronic assembly comprising one or more wire bond stud bumps disposed at one or more locations on a surface of a carrier, and a component fastened to the carrier via the one or more wire bond stud bumps, wherein the component comprises at least one capture feature configured to accommodate at least one of the one or more wire bond stud bumps.

17. The semiconductor package of claim 16, wherein the at least one capture feature comprises one of a milled-out area at edge of the component, an edge castellation, a countersink, a blind hole, a through hole, or any other feature that permits a wire bond stud bump to fit partially or fully within the capture feature.

18. The semiconductor package of claim 16, wherein the at least one capture feature comprises a through hole with tapered walls having a first opening and a second opening that has a larger diameter than that of the first opening.

19. The semiconductor package of claim 18, wherein the component is fastened to the carrier further via at least two wire bond stud bumps having two different diameters, wherein a first of the at least two wire bond stud bumps has a diameter smaller than both first and second openings, and a second of the at least two wire bond stud bumps has a diameter larger than that of the first and smaller than that of the second opening.

20. The semiconductor package of claim 16, wherein the carrier comprises a metal or a metal-clad material and/or wherein the component comprises a non-metallic body having at least one metallized surface.
